(19) United States
(12) Patent Application Publication
(10) Pub. No.: US 2013/0026382 A1
(43) Pub. Date: Jan. 31, 2013

(54) PHOTOVOLTAIC UV DETECTOR

(71) Applicants: Kui Yao, Singapore (SG); Bee Keen Gan, Singapore (SG); Szu Cheng Lai, Singapore (SG)

(72) Inventors: Kui Yao, Singapore (SG); Bee Keen Gan, Singapore (SG); Szu Cheng Lai, Singapore (SG)

(21) Appl. No.: 13/639,504

(22) PCT Filed: Apr. 12, 2011
(86) PCT No.: PCT/SG11/00141

§ 371 Date: Oct. 4, 2012

Related U.S. Application Data
(60) Provisional application No. 61/323,333, filed on Apr. 12, 2010.

(51) Int. Cl. H01L 31/101; H01L 31/11; H01L 31/18; H01L 31/108; H01L 31/102

(52) U.S. Cl. 250/372; 257/431; 257/449; 257/461; 438/98; 257/E31.055; 257/E31.065; 257/E31.068

(57) ABSTRACT

A photovoltaic UV detector configured to generate an electrical output under UV irradiation. The photovoltaic UV detector comprises a first layer comprising an electrically polarized dielectric thin layer configured to generate a first electrical output under the UV irradiation; and a second, layer configured to form an electrical energy barrier at an interface between the second layer and the first layer so as to generate a second electrical output under the UV irradiation, the second electrical output having a same polarity as the first electrical output, the electrical output of the photovoltaic UV detector being a sum of at least the first electrical output and the second electrical output. The electrically polarized dielectric thin layer may be a ferroelectric thin film, which may comprise PZT or PZLT. The second layer may be a metal and the electrical energy barrier may be a Schottky barrier.

### TECHNICAL FIELD

The present invention relates to photovoltaic UV detectors.

### BACKGROUND

Ultraviolet (UV) rays generate pronounced effects on many things, including material structures and properties, chemical reactions, micro-organisms, and other living things. Ultraviolet (UV) irradiation has been widely used in many applications such as materials processing, sterilization, and medical treatment. In these applications, UV intensity has to be carefully controlled, resulting in a need for UV intensity monitoring and dosage measurement.

UV irradiation from sunlight has also been found to be a major cause of skin cancer, tanning, eye cataracts, solar retinitis and corneal dystrophies. However, a small amount of UV is beneficial and even essential for the production of vitamin D in human beings. In addition, because of the variability of skin type and health condition between individuals, UV exposure levels that may cause significant damage to one person may be benign and even beneficial to another. Therefore, it is also desirable for individuals to be able to monitor and manage their own UV exposure using personal portable UV detectors.

Among various existing UV detectors, photon detectors are commonly utilized at UV wavelength due to their great sensitivity. Such UV photon detectors have traditionally been divided into two distinct classes, namely, photographic and photoelectric. Due to their quantitative measurement capability, semiconductor photoelectric detectors are very competitive for precise UV detection. Particularly, photovoltaic semiconductor detectors that generate an electrical output by directly converting UV optical energy into electricity are advantageous because in principle, no electrical bias is required. This allows for continuous UV monitoring and dosage measurement with low or even no power consumption over a specified period of time.

The basic working principles of a photovoltaic semiconductor UV detector are illustrated in FIGS. 1 and 2 (prior art). FIG. 1 (prior art) shows the working principle of a UV detector 10 having a photovoltaic effect at a p-n junction 12 formed between a p-type semiconductor 13 and an n-type semiconductor 14. When the Fermi level of the n-type semiconductor 14 is higher than that of the p-type semiconductor 13, electrons diffuse from the n-type semiconductor 14 to the p-type semiconductor 13 and holes diffuse in an opposite direction. Thus, a positively charged region and a negatively charged region 12 are formed at the interface of the n-type semiconductor 14 and the p-type semiconductor 13 respectively. This electrically charged region 12 is typically called a space charge region 12 or depletion region 12. An electrical field 15 is thus established at the interface 12 with the direction pointing to the p-type semiconductor 13 from the n-type semiconductor 14 as shown. Accordingly, an electrostatic energy barrier is formed. When the p-n junction 12 is irradiated by UV light 11, photo-induced charge carriers comprising photo-induced electrons 16 and photo-induced holes 17 are drifted along two opposite directions as shown under the electric field 15. Consequently, under the UV irradiation 11, an electrical potential is generated as an electrical output 18 over their electrodes 19a and 19b.

FIG. 2 (prior art) shows the working principle of another UV detector 20 having a photovoltaic effect at a metal-semiconductor junction formed when an n-type semiconductor 24 contacts a metal 23 with a larger work function than the n-type semiconductor 24. The work function of a material is the energy required to remove an electron at the Fermi level to the vacuum outside the material. With the larger work function of the metal 23, the Fermi level of the n-type semiconductor 24 is higher than that of the metal 23, and once the two materials 23, 24 are in contact at an interface 29, electrons diffuse from the n-type semiconductor 24 to the metal and holes diffuse in an opposite direction. A positive space charge region 22 is thus formed at the n-type semiconductor 24 near the interface 29. As a result, an electrical field 25 is established at the n-type semiconductor 24 near the interface 29 with the direction pointing to the metal 23 from the n-type semiconductor 24, as shown.

Accordingly, an electrical energy barrier known as a Schottky barrier is formed at the interface 29. The metal layer 23 also functions as a first electrode. A second electrode 23a is provided at a surface of the n-type semiconductor 24 opposite the interface 29. When the metal-semiconductor junction is irradiated by UV light 11, photo-induced charge carriers comprising photo-induced electrons 26 and photo-induced holes 27 are drifted along two opposite directions as shown. Consequently, under UV irradiation, an electrical potential is generated as an electrical output 28 over their electrodes 23 and 23a. A similar Schottky barrier and photovoltaic effects can also be expected when a p-type semiconductor material contacts a metal with a relatively smaller work function.

The semiconductor photovoltaic UV detector 10 has advantages in terms of being able to generate a large current and having a high response speed. However, for applications requiring continuous UV monitoring and UV dosage measurements, such performance properties are not critical. Instead, several problems have been noted, as given below:

(1) As the most commonly used semiconductor material for UV detectors, silicon is not stable under intensive UV irradiation over a long period of time. Consequently, performance of silicon UV detectors under strong UV irradiation often deteriorates over a long irradiation time. Most metals typically used in UV detectors are also unstable under continuous UV irradiation in air. For the metal-semiconductor Schottky UV detector 20, the metal layer 23 is directly exposed to the incident UV light 11, and any material instability can lead to serious deterioration of the photovoltaic UV detector 20 performance. In addition, metal 23 often has poor transparency for UV light. For example, UV light transmission for a polycrystalline Au layer 23 with a thickness of 100 nm is less than 1%.

(2) The magnitude of the photovoltaic output voltage (called photovoltage) is limited by the height of the energy barrier at the interface, which would be the Schottky junction 29 between the metal 23 and the semiconductor material 24, or at the p-n junction 12 for the photovoltaic UV detector 10 using two semiconductors 13 and 14. For both the Schottky junction 29 and the p-n junction 12, the internal electric field 25, 15 that separates the electrons 26, 16 and holes 27,17 only exists at the space charge region 22, 12 of the interface. There is no electric field in the bulk region of the semiconductor 24, 14, 13 outside the space charge region 22, 12.

(3) For some applications, it is desirable to increase the impedance of the semiconductor materials for improving the electrical driving ability of the photovoltaic UV detector for any external circuit.

### SUMMARY

The photovoltaic UV detector described in this application combines the photovoltaic effects of a bulk region of a material used and of at least one interface between materials used in the photovoltaic UV detector. The combined photovoltaic effects constructively contribute to the electrical output of the photovoltaic UV detector under UV illumination. The photovoltaic UV detector comprises an electrically polar dielectric thin layer with an electrical polarization, i.e., an electrically polarized dielectric thin layer, and an electrical energy barrier at a material interface. A first electrical output or photovoltage is produced in the bulk of the electrically polarized dielectric thin layer and a second electrical output or photovoltage is produced at the electrical energy barrier at the material interface. The second electrical output has a same polarity as the first electrical output. The electrical output of the photovoltaic UV detector being a sum of at least the first electrical output and the second electrical output, the first photovoltage and the second photovoltage thus constructively contribute to the electrical output of the photovoltaic UV detector under UV irradiation.

The photovoltaic UV detector of the present invention may comprise a ferroelectric thin layer, a top electrode layer and a bottom electrode layer, in which both the ferroelectric thin layer and the top electrode layer comprise metal oxides, and the magnitude of the work function of the bottom electrode material is larger than the work function of the ferroelectric thin layer and the top electrode material.

In a first exemplary aspect, there is provided a photovoltaic UV detector configured to generate an electrical output under UV irradiation, the photovoltaic UV detector comprising a first layer comprising an electrically polarized dielectric thin layer configured to generate a first electrical output under the UV irradiation; and a second layer configured to form an electrical energy barrier at an interface between the second layer and the first layer so as to generate a second electrical output under the UV irradiation, the second electrical output having a same polarity as the first electrical output, the electrical output of the photovoltaic UV detector being a sum of at least the first electrical output and the second electrical output.

The first electric field comprised in the first layer may be antiparallel to a direction of electrical polarization in the first layer. The first layer is a pyroelectric layer, or more particularly, a ferroelectric thin film.

The photovoltaic UV detector may further comprise a third layer formed on a surface of the first layer opposite the interface between the first layer and the second layer, the third layer being configured to function as a first electrode.

The second layer may be a metal layer and the electrical energy barrier may be a Schottky barrier.

The third layer may be a conductive oxide layer having a smaller work function than the metal layer, and wherein electrical polarization in the first layer is directed from the metal layer to the conductive oxide layer.

The conductive oxide layer may comprise (La,Sr)MnO₃.

Alternatively, the conductive oxide layer may comprise indium-tin oxide.

The first layer may be an n-type material and the metal second layer may have a work function larger than the work function of the first layer.

The metal layer may have a work function larger than 5 eV.

The ferroelectric thin film may comprise (Pb,La)(Zr,Ti)O₃.

The ferroelectric thin film may have a composition of (P_{0.97}La_{0.03})(Zr_{0.52}Ti_{0.48})O₃ and the metal layer may comprise Pt.

The metal layer may be an epitaxial thin film, or it may be polycrystalline.

The ferroelectric thin film may be polycrystalline, or it may be an epitaxial thin film.

The second layer may be configured to function as a second electrode.

The second electrode may be made of an inert metal that is stable under UV irradiation.

Alternatively, the second layer may comprise a semiconductor layer and the electrical energy barrier may be a p-n junction barrier.

The photovoltaic UV detector may further comprise a fourth layer in contact with a surface of the second layer opposite the interface between the first layer and the semiconductor second layer, the fourth layer being configured to function as a second electrode.

The first electrode may form an ohmic contact with the first layer and the second electrode may form an ohmic contact with the second layer.

Alternatively, the first electrode may form a first Schottky barrier with the first layer and the second electrode may form a second Schottky barrier with the second layer.

An electric field comprised in the first Schottky barrier and an electric field comprised in the second Schottky barrier may be aligned with the first electric field and with the second electric field.

The third layer may comprise a metal oxide.

The ferroelectric thin film may comprise a metal oxide.

The photovoltaic UV detector may further comprise a substrate upon which the second electrode is formed.

According to a second exemplary aspect, there is provided a method of forming a photovoltaic UV detector, the method comprising providing a first layer comprising an electrically polarized dielectric thin layer configured to generate a first electrical output under the UV irradiation; and providing a second layer configured to form an electrical energy barrier at an interface between the second layer and the first layer so as to generate a second electrical output under the UV irradiation; such that the second electrical output has a same polarity as the first electrical output and the electrical output of the photovoltaic UV detector may be a sum of at least the first electrical output and the second electrical output.

Step (a) may comprise depositing the dielectric thin layer on the second layer, and electrically polarizing the dielectric thin layer such that a first electric field comprised in the dielectric thin layer has a same direction as a second electric field comprised in the electrical energy barrier at the interface between the dielectric thin layer and the second layer.

The method may further comprise depositing a conductive oxide layer on the dielectric thin layer prior to electrically polarizing the dielectric thin layer, the conductive oxide layer being a first electrode.

The method may further comprise introducing substitutional low valence ions in the dielectric thin layer to produce a p-type dielectric thin layer.

Step (b) may comprise depositing a metal layer as the second layer on a substrate, the metal layer being a second electrode.

Alternatively, step (b) may comprise depositing a metal layer as a second electrode on a substrate, and depositing a semiconductor layer as the second layer on the metal layer.

According to a third exemplary aspect, there is provided a UV detection method comprising exposing a photovoltaic UV detector to UV irradiation, generating a first electrical output under the UV irradiation in a first layer of the photovoltaic UV detector;

generating a second electrical output under the UV irradiation at an electrical energy barrier formed at an interface between the first layer and a second layer of the photovoltaic UV detector, the second electrical output having a same polarity as the first electrical output; and summing at least the first electrical output and the second electrical output to produce an electrical output of the photovoltaic UV detector as a representation of amount of UV irradiation.

### BRIEF DESCRIPTION OF THE DRAWINGS

The invention will now be described, by way of example only, and with reference to the accompanying figures in which:

FIG. 1 (prior art) is a schematic diagram of a UV detector illustrating the working principle of the photovoltaic effect at a p-n junction formed between a p-type semiconductor and a n-type semiconductor.

FIG. 2 (prior art) a schematic diagram of a UV detector illustrating the working principle of the photovoltaic effect at a metal-semiconductor junction (Schottky barrier) formed when a n-type semiconductor contacts a metal with a larger work function.

FIG. 3 is a schematic diagram of a UV detector illustrating the working principle of constructive photovoltaic effects from the bulk region of a n-type ferroelectric layer and a Schottky barrier at a material interface.

FIG. 4 is a schematic diagram a UV detector illustrating the working principle of constructive photovoltaic effects from the bulk region of a n-type ferroelectric layer and a p-n junction at a material interface.

FIG. 5 is a schematic diagram of a UV detector having constructive photovoltaic effects from the bulk region of a ferroelectric layer and a Schottky barrier at a material interface.

FIG. 6 is a graph of experimental output photovoltage from a UV detector at different electric polarizations under UV intensity of 4.35 mW/cm².

FIG. 7 is a graph of experimental output photocurrent from a UV detector at different electric polarizations.

FIG. 8 is a schematic diagram of a UV detector illustrating the working principle of constructive photovoltaic effects from the bulk region of a p-type ferroelectric layer and a Schottky barrier at a material interface.

FIG. 9 is a schematic diagram of a UV detector illustrating the working principle of constructive photovoltaic effects from the bulk region of a p-type ferroelectric layer and a p-n junction at a material interface.

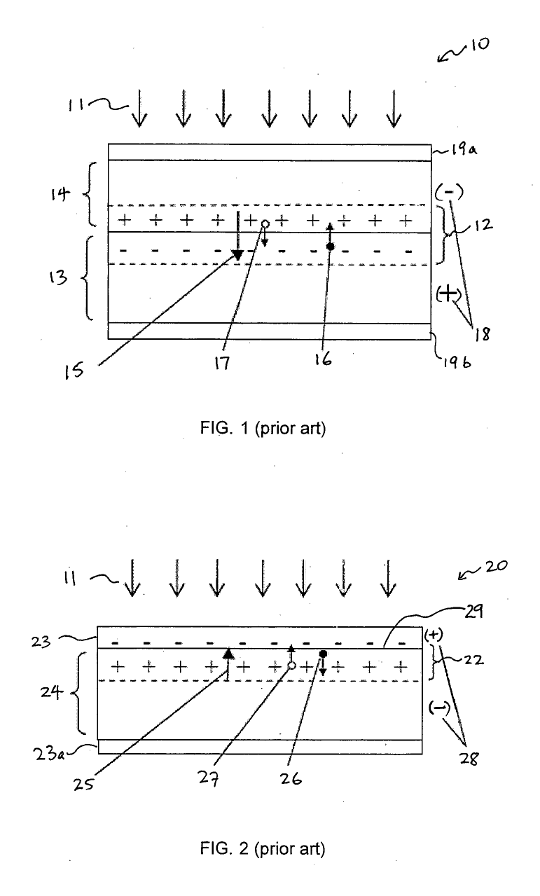

### DETAILED DESCRIPTION OF THE PREFERRED EMBODIMENTS

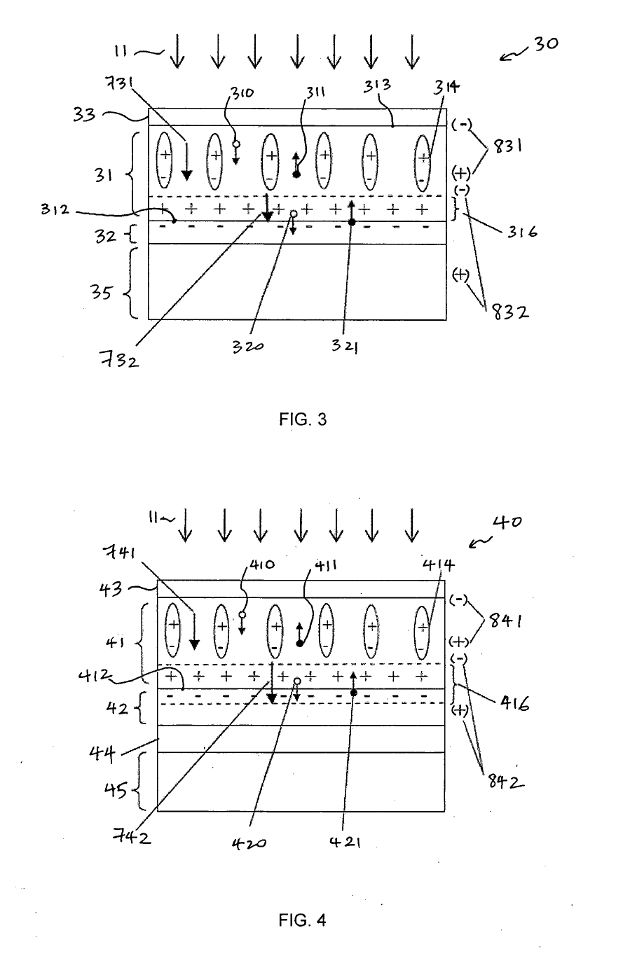

Preferred embodiments of a photovoltaic UV detector according to the present invention will now be described with reference to FIGS. 3 to 9.

FIG. 3 shows a photovoltaic UV detector 30 with electrical output generated under UV irradiation 11 according to a first exemplary embodiment. The photovoltaic UV detector 30 has a multilayer structure. A first layer 31 comprises an electrically polarized dielectric thin layer configured to generate a first electrical output 831 under the UV irradiation 11. A dielectric material is an electrically insulating material with a large electric impedance. Preferably, the electrically polarized dielectric thin layer 31 is a ferroelectric thin film 31 with an oxide composition which is stable in air under UV irradiation. Thus, a first electric field 731 already exists or is comprised in a bulk region of the ferroelectric thin layer 31. Electrons rather than holes are the majority charge carriers in the ferroelectric thin layer 31, and so the ferroelectric thin layer 31 is an n-type ferroelectric.

A second layer 32 is in contact with the first layer 31, the second layer 32 being configured to form an electrical energy barrier at an interface 312 between the second layer 32 and the first layer 31 so as to generate a second electrical output 832 under the UV irradiation 11. In this embodiment, the second layer 32 is a metal having a larger work function than the ferroelectric thin layer 31. Thus, the electrical energy barrier formed at the interface 32 between the ferroelectric thin layer 31 and the second layer 32 is a Schottky barrier. Accordingly, a second electric field 732 exists at the space charge region 316 of the Schottky barrier. Preferably, the first electric field 731 and the second electric field 732 are aligned in a same general direction.

A third layer 33 may be formed on a surface of the first layer 31 opposite the second layer 32 and a smaller Schottky barrier, or preferably no Schottky barrier, is formed between the third layer 33 and the ferroelectric thin layer 31. The third layer 33 functions as a first or top electrode 33, while the second layer 32 functions as a second or bottom electrode 32. Both the top electrode layer 33 and the ferroelectric thin layer 31 may be made of metal oxide materials that are stable under UV irradiation in air. In addition, the oxide top electrode 33 has substantially improved transparency for UV light in comparison with metal. The bottom electrode 32 is preferably made of inert metals that are stable under UV irradiation and have a large work function, such as Pt, and Au.

Polarization 314 of the first layer 31 is preferably aligned in a direction from the bottom electrode 32 to the top electrode 33, while direction of the first electric field 731 is antiparallel to the direction of electrical polarization in the first layer 31.

The UV detector 30 may further comprise a substrate 35 upon which the second electrode 32 is formed.

Under UV irradiation 11, a first electrical or photovoltage output 831 is produced in the bulk of the ferroelectric thin layer 31 because of the first electric field 731 acting on photo-induced holes 310 and electrons 311 in the first layer 31. Likewise, a second electric or photovoltage output 832 is produced at the Schottky barrier at the interface 312 because of the second electric field 732 acting on photo-induced holes 320 and electrons 321 in the Schottky barrier 316. Since the directions of the two electric fields 731, 732 are generally aligned, preferably with a direction from the top electrode 33 to the bottom electrode 32, the second electrical output 832 therefore has a same polarity as the first electrical output 831. The electrical output of the photovoltaic UV detector 30 is a sum of at least the first electrical output 831 and the second electrical output 832. The first photovoltage output 831 and the second photovoltage output 832 thus constructively contribute to the electrical or photovoltage output of the photovoltaic UV detector 30.

The top electrode or third layer 33 is preferably of a different conductive material than the second layer 32, with a relatively smaller work function than the metal of the second layer 32. It is further preferable that the work function of the material of the top electrode 33 is not larger than that of the ferroelectric thin layer 31, so that no electric field exists having a direction opposite to the first and second electric fields 731, 732. Both the ferroelectric thin layer 31 and the top electrode layer 33 preferably have a composition of metal oxides.

In an alternative but not preferred configuration of the first exemplary embodiment, the work function of the material of the top electrode 33 may be larger than that of the ferroelectric thin layer 31, but smaller than that of the bottom electrode 32. In this case, a Schottky barrier is also formed at an interface 313 between the top electrode 33 and the ferroelectric thin layer 31. Accordingly, an unfavorable electric field (not shown) would exist with a direction opposite to that of the first and second electric fields 731, 732. However, because the Schottky barrier at the interface 313 with the top electrode 33 is smaller than the Schottky barrier at the interface 312 with the bottom electrode 32, the photovoltage output 832 at the Schottky barrier at the bottom electrode 32 overweighs that at the top electrode 31. The final output voltage of the photovoltaic UV detector 30 therefore has a same polarity as the first and second photovoltage outputs 831, 832, albeit reduced by the reverse polarity of the photovoltage output at the Schottky barrier at the interface 313 with the top electrode 33.

FIG. 4 shows a photovoltaic UV detector 40 with electrical output generated under UV irradiation 11 according to a second exemplary embodiment. The photovoltaic UV detector 40 device has a multilayer structure. A first layer 41 comprises an electrically polarized dielectric thin layer configured to generate a first electrical output 841 under the UV irradiation 11. Preferably, the electrically polarized dielectric thin layer 41 is a ferroelectric thin film 41 with an oxide composition which is stable in air under UV irradiation. Thus, a first electric field 741 already exists or is comprised in a bulk region of the ferroelectric thin layer 41. Electrons rather than holes are the majority charge carriers in the ferroelectric thin layer 41, and so the ferroelectric thin layer 41 is an n-type ferroelectric.

A second layer 42 is in contact with the first layer 41, the second layer 42 being configured to form an electrical energy barrier at an interface 412 between the second layer 42 and the first layer 41 so as to generate a second electrical output 842 under the UV irradiation 11. In this second exemplary embodiment, the second layer 42 is a semiconductor layer 42. The majority charge carriers in the semiconductor layer 42 are holes, therefore the second layer 42 is a p-type semiconductor.

Consequently, a p-n junction with an electrical energy barrier is formed between the ferroelectric thin layer 41 and the p-type semiconductor layer 42, and accordingly a second electric field 742 exists or is comprised at the space charge region 416 of the p-n junction.

A third layer 43 may be formed on a surface of the first layer 41 opposite the second layer 42 and a smaller Schottky barrier, or preferably no Schottky barrier, is formed between the third layer 43 and the ferroelectric thin layer 41. The third layer 43 functions as a first or top electrode 43. Both the top electrode layer 43 and the ferroelectric thin layer 41 may be made of metal oxide materials that are stable under UV irradiation in air. In addition, the oxide top electrode 43 has substantially improved transparency for UV light in comparison with metal.

A fourth layer 44 functioning as a second or bottom electrode 44 may be provided on a surface of the second layer 42 opposite the first layer 41. The bottom electrode 44 is preferably made of inert metals that are stable under UV irradiation and have a large work function, such as Pt, and Au.

Electrical polarization 414 of the first layer 41 is preferably aligned in a direction from the bottom electrode 44 to the top electrode 43, while direction of the first electric field 741 is antiparallel to the direction of electrical polarization in the first layer 41. The UV detector 40 may further comprise a substrate 45 upon which the second electrode 44 is formed.

Under UV irradiation 11, a first electrical or photovoltage output 841 is produced in a bulk region of the ferroelectric thin layer 41 because of the first electric field 741 acting on photo-induced holes 410 and electrons 411 in the first layer 41. A second electrical or photovoltage output 842 is produced at the p-n junction 416 because of the second electric field 742 acting on photo-induced holes 420 and electrons 421 in the p-n junction 416.

Since the directions of the two electric fields 741, 742 are generally aligned, preferably with a direction from the top electrode 43 to the bottom electrode 44, the second electrical output 842 therefore has a same polarity as the first electrical output 841. The electrical output of the photovoltaic UV detector 40 is a sum of at least the first electrical output 841 and the second electrical output 842. The first photovoltage output 841 and the second photovoltage output 842 thus constructively contribute to the electrical or photovoltage output of the photovoltaic UV detector 40.

In an alternative configuration to the second exemplary embodiment, the top and bottom electrode layers 43, 44 could form ohmic contacts with the ferroelectric thin layer 41 and the semiconductor layer 42 respectively.

In a further alternative configuration, the top and bottom electrode layers 43, 44 form Schottky barriers with the ferroelectric thin layer 41 and the semiconductor layer 42 respectively, such that the electric field at their corresponding electric energy barriers are aligned with the first and second electric fields 741, 742.

In yet another alternative but not preferred configuration, one or both of the top and bottom electrode layers 43, 44 form one or two Schottky barriers with the ferroelectric thin layer 41 and the semiconductor layer 42 respectively, such that the electric field at the corresponding electric energy barriers are antiparallel with the first and second electric fields 741, 742. However, the height of the one or two Schottky barriers is smaller than the energy barrier of the p-n junction 416 so that the photovoltage output 842 at the p-n junction 416 outweighs the opposing photovoltage at the one or two Schottky barriers. The electrical output of the photovoltaic UV detector 40 being a sum of the first electrical output 841, the second electrical output 842 and also the reverse photovoltage output at the one or two Schottky barriers, the final output voltage of the photovoltaic UV detector 40 is therefore still in a same polarity as the first and second electrical or photovoltage outputs 841, 842, although the magnitude is reduced due to the reverse photovoltage output polarity at the one or two Schottky barriers.

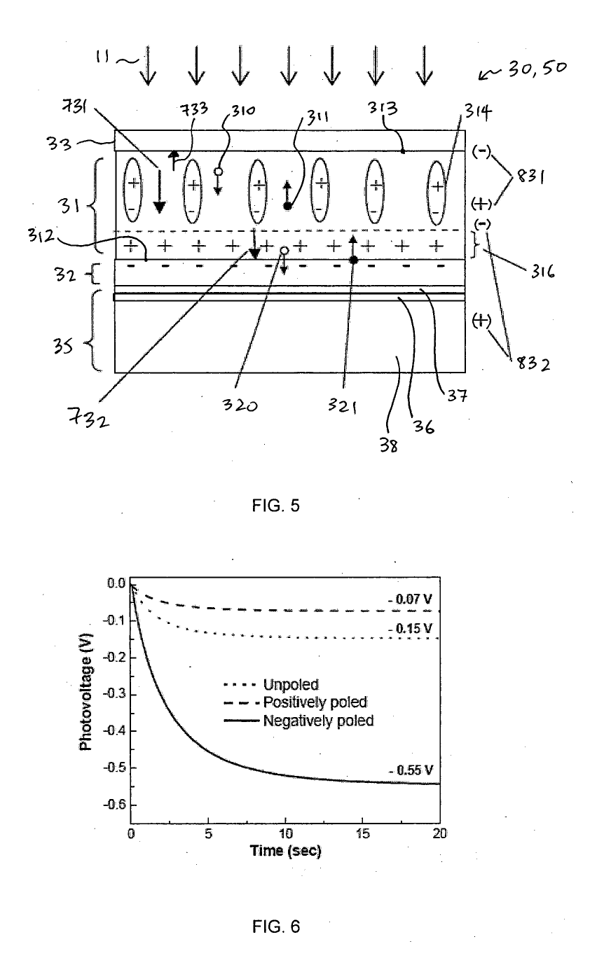

A fabrication process for making a photovoltaic UV detector 30, 50 according to the first exemplary embodiment of FIG. 3 will be described below, with further reference to FIG. 5. The fabrication begins with forming a silicon oxide (SiO₂) layer 36 with a thickness of 0.5 μm by thermal oxidation on a 4-inch single crystal silicon wafer 38 with (100) orientation. A titanium (Ti) layer 37 of 0.05 μm in thickness is then deposited by sputtering on top of the SiO₂ layer to form a Ti/SiO₂/Si wafer substrate 35. A platinum (Pt) layer 32 of 0.1 to 0.5 μm in thickness is deposited by sputtering Pt on top of the Ti layer 37. The Ti layer 37 is introduced to improve adhesion of the Pt layer 32 on the SiO₂ layer 36. A ferroelectric ceramic thin layer 31 with a composition of (P_{0.97}La_{0.03})(Zr_{0.52}Ti_{0.48})O₃ (PLZT) is then deposited on top of the Pt layer 32.

A number of methods may be used to deposit the ferroelectric PLZT thin layer 31 on the Pt layer 32, including chemical solution coating, sputtering, chemical vapor deposition, and pulsed laser deposition. In an exemplary embodiment, a chemical solution approach is used for the deposition, in which a precursor solution is first prepared from lead acetate trihydrate, lanthanum acetate, zirconium acetylacetonate, and titanium isopropoxide dissolved in 2 methoxyethanol (2-MOE). The precursor solution is then spin coated on top of the Pt layer 32 on the Ti/SiO₂/Si wafer substrate 35, followed by drying at 100° C. and pyrolysis at 430° C. After multiple cycles of coating and pyrolysis to obtain the targeted thickness, the ferroelectric PLZT thin layer 31 is annealed at a final temperature of 600 to 700° C. for 10 minutes with a ramping rate of 10° C./sec, to obtain a PLZT layer 31 with a thickness of 1.1 μm by the repeated spin coating process.

A conductive oxide layer 33 with composition of (La_{0.7}Sr_{0.3})MnO₃ (LSMO) is then prepared on top of the PLZT thin layer 31 by sputtering and patterning using a shadow mask made of silicon. The deposition of, the oxide conductive layer 33 is performed under DC mode at 60 W with a gas ratio of Ar:O₂=50:50 and a working pressure of 3.8 mTorr. After the deposition, the LSMO layer 33 is post-annealed at 650 to 700° C. The thickness of the LSMO electrode 33 is about 200 nm. A same thickness of LSMO electrode 33 may also be deposited by RF sputtering at 100 W with a gas ratio of Ar:O₂=60:100 and a working pressure of 5.5 mTorr.

The Pt layer 32 is used as the bottom electrode 32 and the LSMO layer 33 is used as the top electrode 33 for the ferroelectric PLZT layer 31. They 32, 33 are also used as two electrical terminals for the overall electrical output of the UV detector 30. The multilayer structure of the exemplary embodiment of FIG. 3 is shown in FIG. 5.

To electrically polarize the ferroelectric PLZT layer 31, first, a part of the bottom electrode (Pt) 32 may be exposed by a wet-etching process of the PLZT layer with a mixed etching solution of HNO₃ and HF after patterning a spin-coated photoresist layer with a standard photolithography process. An external electric field of 150 kV/cm is then applied between the LSMO top electrode layer 33 and the Pt layer 32 to electrically polarize the ferroelectric PLZT layer 31. To achieve the desired electrical polarization direction 314, the positive terminal of the external electric field is connected to the Pt bottom electrode 32, which is termed as negative polarization. Accordingly, the electrical polarization 314 in the ferroelectric PLZT thin layer 31 is aligned in the thickness direction pointing from the Pt layer 32 to the LSMO layer 33. After removal of the external electric field, only an internal electric field, referred to as the first electric field 731, exists at the bulk region of the PLZT thin layer 31 with the direction from the LSMO layer 33 to the Pt layer 32.

For the PLZT thin layer 31 with the specified composition and prepared following the processing steps and conditions described above, electrons rather than holes are the majority charge carriers, and the PLZT thin layer 31 is an n-type ferroelectric. The Pt electrode layer 32 has a work function of about 5.1 to 6.0 eV, which is larger than the work function of 3.0 to 4.0 eV for the PLZT thin layer 31. Thus a Schottky barrier 316 is formed between the PLZT thin layer 31 and the Pt bottom electrode 32, and accordingly a second electric field 732 is established at the space charge region 316 near the interface 312 between the PLZT layer 31 and the Pt layer 32. The two electric fields 731, 732 are aligned in the same, direction along the thickness of the layers 31, 32.

Under UV irradiation 11, a first photovoltage output 831 is produced in the bulk region of the ferroelectric PLZT thin layer 31 because of the first electric field 731 acting on photo-induced holes 310 and electrons 311 in the PLZT thin layer 31. Similarly, a second photovoltage output 832 is produced because of the second electric field 732 acting on photon-induced holes 320 and electrons 321 at the Schottky barrier 316 at the interface 312. Since the directions of the two electric fields 731, 732, are aligned, the second electrical output 832 has a same polarity as the first electrical output 831. The electrical output of the photovoltaic UV detector 30, 50 is a sum of at least the first electrical output 831 and the second electrical output 832. The first photovoltage output 831 and the second photovoltage output 832 thus constructively contribute to the photovoltage output of the photovoltaic UV detector 30, 50.

The top LSMO electrode layer 33 has a work function of 4.8 to 4.9 eV, which is larger than that of the ferroelectric thin layer 31, but smaller than that of the Pt bottom electrode 32. In this embodiment, a Schottky barrier is also farmed at the interface 313 between the LSMO top electrode 33 and the PLZT thin layer 31. Thus, an unfavorable opposing electric field 733 exists with a direction opposite to the two electric fields 731, 732. However, because the Schottky barrier at the LSMO interface 313 is smaller than that at the Pt interface 312, the photovoltage output 832 at the Schottky barrier at the Pt bottom electrode 32 overweighs that at the LSMO top electrode 33.

Experimental measurements have shown that the LSMO top electrode 33 has greatly improved transparency for UV light in comparison with metals such as gold (Au). At least 15% of UV light having a wavelength of 365 nm can pass through a polycrystalline LSMO layer 33 with a thickness of 200 nm. By contrast, UV light transmission is below 1% for a polycrystalline Au layer with a thickness of 100 nm in a UV detector of the type shown in FIG. 2 (prior art).

FIG. 6 shows the measured photovoltage output of a sample photovoltaic UV detector 30, 50 of FIG. 5 at various states of electrical polarization of the PLZT layer 31. A xenon-mercury lamp was used as the UV light source having a peak intensity at 365 nm. When the PLZT layer 31 was not electrically polarized, i.e., it was unpoled since no electric field had been applied to orientate the electric polarization, no net polarization and no electric field existed along any direction in the bulk region of the PLZT layer 31. A photovoltage of −0.15 V was observed. This photovoltage of −0.15 V may be attributed to the photovoltaic effects due to the second electric field 732 at the Schottyky barrier interface of the Pt layer 32 with the PLZT layer 31, and to the unfavourable opposing electric field 733 formed at the Schottky barrier at the interface 313 between the LSMO top electrode 33 and the PLZT thin layer 31. The directions of the two Schottky barrier electric fields 732, 733 being opposite to each other, the observed photovoltage of −0.15 V was thus mainly from the second electric field 732 arising from the Schottky barrier with the Pt layer 32 after deducting the opposing photovoltage from the unfavourable electric field 733 arising from the Schottky barrier with the LSMO layer 33. Practically, a Schottky barrier height and the photovoltage derived from the Schottky barrier can be significantly lower than the ideally theoretical value due to surface states and any contaminations at the material interfaces 312, 313.

When the PLZT layer 31 was positively poled with the LSMO top electrode 33 as the positive terminal during the electrical polarization process, the polarization 314 in the PLZT layer 31 was directed from the LSMO layer 33 to the Pt layer 32. The first electric field 731 in the bulk region of the PLZT layer 31 was directed opposite to the direction of the second electric field 732 at the Schottky barrier at the interface 312 with the Pt layer 32. Accordingly, a further reduced photovoltage output of the UV detector 30, 50 was observed to be −0.07 V, due to the second photovoltage output 832 being further reduced by the opposing first photovoltage output 831 as well as the opposing photovoltage due to the unfavourable opposing electric field 733.

When the PLZT layer 31 was negatively poled with the LSMO top electrode 33 as the negative terminal during the electrical polarization process, polarization in the PLZT layer 31 was directed from the Pt layer 32 to the LSMO layer 33. The first electric field 731 in the bulk region of the PLZT layer 31 became aligned with the second electric field 732 at the Schottky barrier at the interface 312 with the Pt layer 32, both being directed from the LSMO layer 33 to the Pt layer 32. Thus, a significantly enhanced photovoltage of −0.55 V was observed, due to the first photovoltage output 831 having a same polarity as the second photovoltage output 832, thereby constructively contributing to the electrical or photovoltage output of the photovoltaic UV detector 30,50.

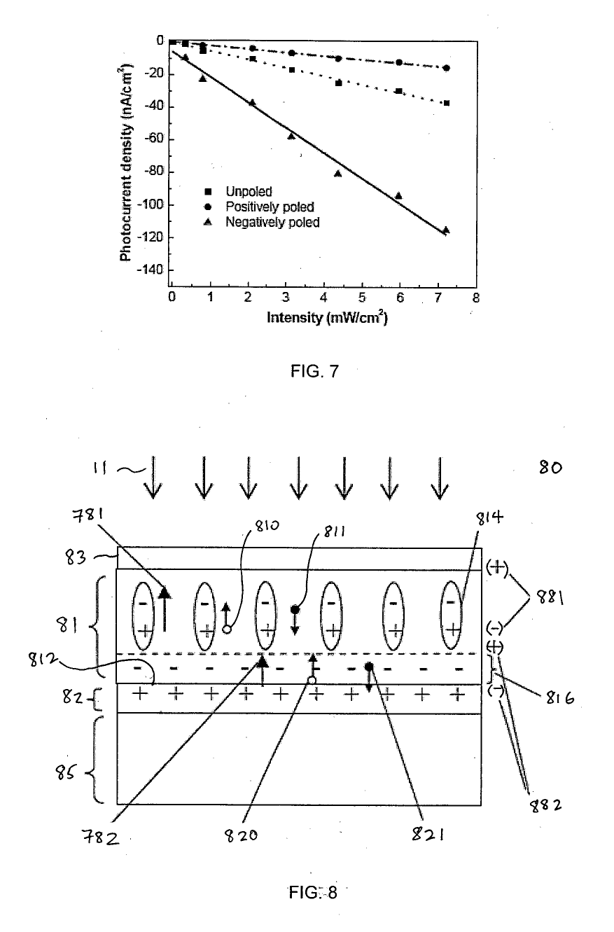

Short circuit photocurrent outputs of the UV detector 50 of FIG. 5 under the three different electrical polarization states of unpoled, positively poled and negatively poled are presented in FIG. 7. When the PLZT layer 31 was negatively poled with the LSMO top electrode 33 as the negative terminal during the electrical polarization process, the first electric field 731 in the bulk region of the PLZT layer 31 was aligned with the second electric field 732 at the Schottky barrier at the interface 312 with the Pt layer 32. Thus, a significantly enhanced photocurrent was obtained.

Expectedly, when the PLZT layer 31 was positively poled with the LSMO top electrode 33 as the positive terminal during the electrical polarization process, the first electric field 731 in the bulk region of the PLZT layer 31 was opposing the second electric field 732 at the Schottky barrier at the interface 312 with the Pt layer 32. Thus, a significantly reduced photocurrent was obtained.

Many other metal oxides, including indium-tin-oxide (ITO) (4.3-4.7 eV), SrRuO₃ (SRO) (4.6-5.0 eV), (La,Sr)CoO₃ (LSCO) (4.65 eV), (Sr,Ru)O₂ (4.25-4.75 eV), IrO₂ (4.23 eV), and Nb-doped SrTiO₃ (Nb—STO) (4.2 eV), have smaller work functions than the Pt layer 32 (5.1-6.3 eV). Therefore, it is envisaged that any of them may be used as the third or top electrode layer 33 to provide a similar effect as that provided by the LSMO layer 33.

For the first layer 31, PLZT may be replaced by many other ferroelectric compositions, for example, PbTiO₃, Pb(Zr,Ti)O₃; BaTiO₃, Pb(Mg,Nb)O₃, Pb(Zn;Nb)O₃, Pb(Ni,Nb)O₃, LiNbO₃, LiTaO₃, (K,Na)NbO₃, Bi₄Ti₃O₁₂, BiFeO₃, and (Ba,Sr)Nb₂O₆. In addition, since all pyroelectric materials could have polarization along their polar axes, therefore not only ferroelectric materials but all pyroelectric materials with net polarization along their thickness direction may be used to replace the PLZT, including ZnO, GaN, which are not ferroelectric materials.

The Pt layer 32 and the ferroelectric PLZT layer 31 in the embodiment of FIG. 5 are polycrystalline with random crystallographic orientation since they are deposited on the amorphous SiO₂ layer 36 on the silicon wafer 38. If higher sensitivity is required, epitaxial PLZT and Pt films can be deposited as the first layer 31 and the second layer 32 respectively on selected oxide single crystal substrates. For example, epitaxial Pt layer with (100) or (111) orientation may be deposited on (100)- or (111)-oriented MgO single crystal substrate by sputtering or e-beam evaporation. Subsequently, epitaxial PLZT layer with (100) or (111) orientation can be grown on the (100)- or (111)-oriented epitaxial Pt layer, by any of the known thin film deposition methods, including chemical solution coating, sputtering, chemical vapor deposition, and pulsed laser deposition. With the epitaxial quality of the PLZT and Pt, greatly enhanced photovoltage and photocurrent output can be obtained in comparison with the polycrystalline PLZT and Pt layers having a random orientation.

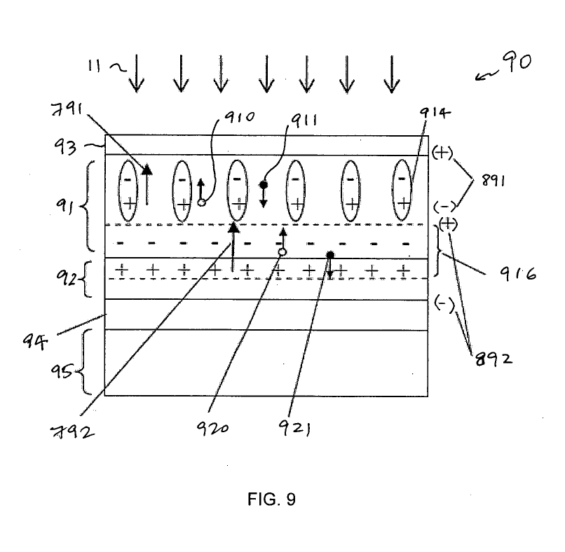

In a third exemplary embodiment of a photovoltaic UV detector 80 as shown in FIG. 8, an electrically polarized p-type ferroelectric layer 81 may be produced to function as the first layer 81, for example, by introducing substitutional low valence ion in the crystal lattice of lead zirconate titanate (PZT), so that holes are the majority charge carriers. A first electric field 781 thus exists or is comprised in a bulk region of the p-type ferroelectric thin layer 81. A Schottky barrier is formed when the first layer 81 contacts with a metal second layer 82 as the bottom electrode 82 having a smaller work function than the first layer 81. Accordingly, a second electric field 782 exists at the space charge region 816 of the Schottky barrier. Preferably, the first electric field 781 and the second electric field 782 are aligned in a same direction

A third layer 83 functioning as a top electrode 83 may be formed on a surface of the first layer 81 opposite the second layer 82. In this embodiment, electrical polarization 814 of the first layer 81 is preferably aligned in a direction from the top electrode 83 to the bottom electrode 82, while direction of the first electric field 781 is antiparallel to the direction of electrical polarization in the first layer 81. The UV detector 80 may further comprise a substrate 85 upon which the second electrode 82 is formed.

Under UV irradiation 11, a first photovoltage output 881 is produced in the bulk of the ferroelectric thin layer 81 because of the first electric field 781 acting on photo-induced holes 810 and electrons 811 in the first layer 81. Likewise, a second electric output 882 is produced at the Schottky barrier at the interface 812 because of the second electric field 782 acting on photo-induced holes 820 and electrons 821 in the Schottky barrier 816. Since the directions of the two electric fields 781, 782 are aligned, preferably with a direction from the bottom electrode 82 to the top electrode 83, the second electrical output 882 therefore has a same polarity as the first electrical output 881. The first photovoltage output 881 and the second photovoltage output 882 are thus aligned so as to constructively contribute to the photovoltage output of the photovoltaic. UV detector 80.

In a fourth exemplary embodiment of the photovoltaic UV detector 90 as shown in FIG. 9, a p-n junction 916 can be formed when an electrically polarized p-type ferroelectric film functioning as the first layer 91 contacts an n-type semiconductor functioning as the second layer 92. A first electric field 791 thus already exists or is comprised in a bulk region of the p-type ferroelectric thin layer 91. A second electric field 792 exists or is comprised at the space charge region 916 of the p-n junction. A third layer 93 may be formed on a surface of the first layer 91 opposite the second layer 92. The third layer 93 functions as a first or top electrode 93. A fourth layer 94 functioning as a second or bottom electrode 94 may be provided on a surface of the second layer 92 opposite the first layer 91.

Electrical polarization 914 of the first layer 91 is preferably aligned in a direction from the top electrode 93 to the bottom electrode 94, while direction of the first electric field 791 is antiparallel to the direction of electrical polarization in the first layer 91. The UV detector 90 may further comprise a substrate 95 upon which the second or bottom electrode 94 is formed.

Under UV irradiation 11, a first photovoltage output 891 is produced in a bulk region of the p-type ferroelectric thin layer 91 because of the first electric field 791 acting on photo-induced holes 910 and electrons 911 in the first layer 91. A second photovoltage output 892 is produced at the p-n junction 916 because of the second electric field 792 acting on photo-induced holes 920 and electrons 921 in the p-n junction 916.

Since the directions of the two electric fields 791, 792 are aligned, preferably with a direction from the bottom electrode 94 to the top electrode 93, the second electrical output 892 therefore has a same polarity as the first electrical output 891. The first photovoltage output 891 and the second photovoltage output 892 are thus aligned so as to constructively contribute to the photovoltage output of the photovoltaic UV detector 90.

Since the metal oxide ferroelectric thin layer and the top electrode that is directly exposed to the incident UV light have good stability in air under UV irradiation, the photovoltaic UV detector can have an improved stability over a long time and under intensive UV irradiation. This makes it suitable for continuous monitoring of UV irradiation having large intensity and dosage measurement over a long period.

As described above, in the preferred exemplary embodiments of the photovoltaic UV detector 30, 40, constructive photovoltaic effect from the bulk of the dielectric thin layer 31, 41 and its interface with the second layer 32, 42 leads to significant improvement in the electrical output of the UV detector 30, 40. As an insulating material, the ferroelectric layer 31 also has a large electrical impedance. These features can improve the circuit driving capability of the photovoltaic UV detector 30, 40.

The photovoltaic UV detectors as described above generate a photovoltage or electrical output by directly converting the received UV light energy into electricity, thereby having significant advantages over other UV detectors since no electrical bias is required for operation, in principle. This feature is particularly desirable for continuous UV monitoring or UV dosage measurement over a specified period of time.

The materials used to prepare the photovoltaic UV detectors as described above also have better stability under continuous and intensive UV irradiation, so as to be suitable for producing photovoltaic UV detectors according to the present invention for continuously monitoring intensive UV irradiation and dosage measurement over a long period.

Whilst there has been described in the foregoing description preferred embodiments of the present invention, it will be understood by those skilled in the technology concerned that many variations or modifications in details of design or construction may be made without departing from the present invention.

1. A photovoltaic UV detector configured to generate a electrical output under UV irradiation, the photovoltaic UV detector comprising:
a first layer comprising an electrically polarized dielectric thin layer configured to generate a first electrical output under the UV irradiation; and
a second layer configured to form an electrical energy barrier at an interface between the second layer and the first layer so as to generate a second electrical output under the UV irradiation, the second electrical output having a same polarity as the first electrical output, the electrical output of the photovoltaic UV detector being a sum of at least the first electrical output and the second electrical output.

2. The photovoltaic UV detector of claim 1, wherein a first electric field comprised in the first layer is antiparallel to a direction of electrical polarization in the first layer.

3. The photovoltaic UV detector of any preceding claim, wherein the first layer is a pyroelectric layer.

4. The photovoltaic UV detector of claim 3, wherein the first layer is a ferroelectric thin film.

5. The photovoltaic UV detector of any preceding claim, further comprising a third layer formed on a surface of the first layer opposite the interface between the first layer and the second layer, the third layer being configured to function as a first electrode.

6. The photovoltaic UV detector of any preceding claim, wherein the second layer is a metal layer and the electrical energy barrier is a Schottky barrier.

7. The photovoltaic UV detector of claim 6 when dependent on claim 5, wherein the third layer is a conductive oxide layer having a smaller work function than the metal layer, and wherein electrical polarization in the first layer is directed from the metal layer to the conductive oxide layer.

8. The photovoltaic UV detector of claim 7, wherein the conductive oxide layer comprises (La,Sr)MnO₃.

9. The photovoltaic UV detector of claim 7, wherein the conductive oxide layer comprises indium-tin oxide.

10. The photovoltaic UV detector of any one of claims 6 to 9, wherein the first layer is an n-type material and the metal second layer has a work function larger than the work function of the first layer.

11. The photovoltaic UV detector of claims 10, wherein the metal layer has a work function larger than 5 eV.

12. The photovoltaic UV detector device of any one of claims 6 to 11 when dependent on claim 5, wherein the ferroelectric thin film comprises (Pb,La)(Zr,Ti)O₃.

13. The photovoltaic UV detector device of claim 12 when dependent on claim 8, wherein the ferroelectric thin film has a composition of (P_{0.97}La_{0.03})(Zr_{0.52}Ti_{0.48})O₃ and the metal layer comprises Pt.

14. The photovoltaic UV detector device of any one of claims 6 to 13, wherein the metal layer is an epitaxial thin film.

15. The photovoltaic UV detector device of any one of claims 6 to 13, wherein the metal layer is polycrystalline.

16. The photovoltaic UV detector device of any one of claims 6 to 15 when dependent on claim 5, wherein the ferroelectric thin film is polycrystalline.

17. The photovoltaic UV detector device as claimed in 6 to 14 when dependent on claim 4, wherein the ferroelectric thin film is an epitaxial thin film.

18. The photovoltaic UV detector of any preceding claim, the second layer being configured to function as a second electrode.

19. The photovoltaic UV detector of claim 18, the second electrode being made of an inert metal that is stable under UV irradiation.

20. The photovoltaic UV detector of any one of claims 1 to 5, wherein the second layer comprises a semiconductor layer and the electrical energy barrier is a p-n junction barrier.

21. The photovoltaic UV detector of claim 20, further comprising a fourth layer in contact with a surface of the second layer opposite the interface between the first layer and the second layer, the fourth layer being configured to function as a second electrode.

22. The photovoltaic UV detector of claim 21, wherein the first electrode forms an ohmic contact with the first layer and the second electrode forms an ohmic contact with the second layer.

23. The photovoltaic UV detector of claim 21, wherein the first electrode forms a first Schottky barrier with the first layer and the second electrode forms a second Schottky barrier with the second layer.

24. The photovoltaic UV detector of claim 23, wherein an electric field comprised in the first Schottky barrier and an electric field comprised in the second Schottky barrier are aligned with the first electric field and with the second electric field.

25. The photovoltaic UV detector of any one of claims 20 to 24 when dependent on claim 5, wherein the third layer comprises a metal oxide.

26. The photovoltaic UV detector of any one of claims 20 to 25 when dependent on claim 5, wherein the ferroelectric thin film comprises a metal oxide.

27. The photovoltaic UV detector of claim 18, 19 or any one of claims 22 to 26 when dependent on claim 21, further comprising a substrate upon which the second electrode is formed.

28. A method of forming a photovoltaic UV detector, the method comprising:
(a) providing a first layer comprising an electrically polarized dielectric thin layer configured to generate a first electrical output under the UV irradiation; and
(b) providing a second layer configured to form an electrical energy barrier at an interface between the second layer and the first layer so as to generate a second electrical output under the UV irradiation; such that the second electrical output has a same polarity as the first electrical output and the electrical output of the photovoltaic UV detector is a sum of at least the first electrical output and the second electrical output.

29. The method of claim 28, wherein step (a) comprises depositing the dielectric thin layer on the second layer, and electrically polarizing the dielectric thin layer such that a first electric field comprised in the dielectric thin layer has a same direction as a second electric field comprised in the electrical energy barrier at the interface between the dielectric thin layer and the second layer.

30. The method of claim 29, further comprising depositing a conductive oxide layer on the dielectric thin layer prior to electrically polarizing the dielectric thin layer, the conductive oxide layer being a first electrode.

31. The method of any one of claims 28 to 30, further comprising introducing substitutional low valence ions in the dielectric thin layer to produce a p-type dielectric thin layer.

32. The method of any one of claims 28 to 31, wherein step (b) comprises depositing a metal layer as the second layer on a substrate, the metal layer being a second electrode.

33. The method of claim any one of claims 28 31, wherein step (b) comprises depositing a metal layer as a second electrode on a substrate, and depositing a semiconductor layer as the second layer on the metal layer.

34. A UV detection method comprising:
exposing a photovoltaic UV detector to UV irradiation,
generating a first electrical output under the UV irradiation in a first layer of the photovoltaic UV detector;
generating a second electrical output under the UV irradiation at an electrical energy barrier formed at an interface between the first layer and a second layer of the photovoltaic UV detector, the second electrical output having a same polarity as the first electrical output; and
summing at least the first electrical output and the second electrical output to produce an electrical output of the photovoltaic UV detector as a representation of amount of UV irradiation.
